(19) United States
(12) Patent Application Publication
(10) Pub. No.: US 2021/0408439 A1
(43) Pub. Date: Dec. 30, 2021

(54) ORGANIC LIGHT EMITTING ELEMENT, DISPLAY DEVICE, AND MANUFACTURING METHOD OF ORGANIC LIGHT EMITTING ELEMENT

(71) Applicant: Wuhan China Star Optoelectronics Semiconductor Display Technology Co., Ltd., Hubei (CN)

(72) Inventor: Junyuan Wang, Hubei (CN)

(21) Appl. No.: 16/644,914

(22) PCT Filed: Nov. 18, 2019
(86) PCT No.: PCT/CN2019/119284

§ 371 Date: Mar. 5, 2020

(30) Foreign Application Priority Data
Jul. 30, 2019 (CN) 201910695797.4

(51) Int. Cl. H01L 51/52; H01L 27/32; H01L 51/56

(52) U.S. Cl. CPC H01L 51/5228; H01L 27/3234; H01L 2227/323; H01L 51/5253; H01L 51/56; H01L 27/3246

(57) ABSTRACT

An organic light emitting element, a display device, and a manufacturing method of an organic light emitting element are provided. The organic light emitting element is provided with a display area and a camera under panel area. The camera under panel area includes an array substrate, a pixel definition layer, an anode layer, a plurality of sub-pixels, and at least one cathode line. The cathode line is provided on the pixel definition layer and connected to the plurality of sub-pixels in series. The display device includes an organic light emitting element and a sensor, and a camera area is provided to correspond to a position of the sensor.

### FIELD OF DISCLOSURE

The present disclosure relates to the field of display, and particularly relates to an organic light emitting element, a display device, and a manufacturing method of an organic light emitting element.

### BACKGROUND OF DISCLOSURE

An organic light emitting diode (OLED) has characteristics of self-illumination, fast response times, and wide viewing angles, and thus has a wide application prospect. At present, an OLED display screen is developing to a high screen-to-body ratio, and a notch screen, a water drop notch screen, a full screen. Namely, the technology of using a camera under panel (CUP), emerge as the times require.

Since the camera under panel (CUP) can achieve a display function by a special design, and achieve a screen-to-body ratio of 100%, the application prospect thereof is wide. Further, since a pixel definition layer (PDL), an anode layer, and a cathode layer have poor transmittance, the transmittance of visible light in the camera under panel area is low, which significantly affects the intensity of light passing through the camera under panel area.

### SUMMARY OF DISCLOSURE

### Technical Problems

The purpose of the present disclosure is to provide an organic light emitting element, a display device, and a manufacturing method of the organic light emitting element, so as to solve the technical problem of low transmittance in the camera under panel (CUP) area, thereby improving the intensity of light passing through the camera under panel area, and enhancing the photosensitivity of the camera under panel in the camera under panel area.

### Technical Solutions

To solve the above problem, the present disclosure provides an organic light emitting element provided with a display area and a camera under panel area. The camera under panel area comprises an array substrate, a pixel definition layer, an anode layer, a plurality of sub-pixels, and at least one cathode line. The pixel definition layer is provided on the array substrate and provided with a plurality of recesses. The anode layer is provided in the recesses. The plurality of sub-pixels are provided on the anode layer in corresponding recesses. The cathode line is provided on the pixel definition layer and connected to the plurality of sub-pixels in series, and two ends of the cathode line extend and are electrically connected to a cathode layer located in the display area.

Further, the cathode line is linear, wavy, arc-shaped, or S-shaped.

Further, the sub-pixels comprise a light emitting layer and a cathode layer. The light emitting layer is provided on the anode layer in the corresponding recess. The cathode layer is provided on the light emitting layer and completely covers an upper surface of the light emitting layer. The cathode layer is electrically connected to the cathode line.

Further, the sub-pixels comprise at least one red sub-pixel, at least one green sub-pixel, and at least one blue sub-pixel.

Further, the organic light emitting element further comprises a thin film encapsulation layer provided on the cathode line.

The present disclosure further provides a display device comprising the aforementioned organic light emitting element and a sensor, wherein the camera under panel area is disposed corresponding to a position of the sensor.

Further, the sensor comprises one or a combination of a camera sensor, a breathing light sensor, a distance sensor, a fingerprint scanner sensor, a microphone sensor, and a transparent antenna sensor.

The present disclosure further provides a manufacturing method of an organic light emitting element comprising steps as follows.

A pixel definition layer is prepared on the array substrate, and a plurality of recesses are prepared in the pixel definition layer.

An anode layer is prepared on the pixel definition layer.

A plurality of sub-pixels are prepared on the anode layer in corresponding recesses.

At least one cathode line is prepared on the pixel definition layer. The cathode line is connected to the plurality of sub-pixels in series, and two ends of the cathode line extend and are connected to a cathode layer in the display area.

Further, the manufacturing method of the organic light emitting element further comprises steps as follows. A thin film encapsulation layer is prepared on the cathode line.

Further, the step of preparing the sub-pixels comprises steps as follows.

A light emitting layer is prepared on the anode layer in the corresponding recess.

A cathode layer is prepared on the light emitting layer. The cathode layer completely covers an upper surface of the light emitting layer. The cathode layer is electrically connected to the cathode line.

### Beneficial Effects

The beneficial effect of the present disclosure is as follows. An organic light emitting element, a display device, and a manufacturing method of the organic light emitting element are provided. By replacing the cathode layer located in the camera under panel area with the cathode line, the transmittance in the camera under panel area is improved, thereby improving the intensity of light passing through the camera under panel area, and enhancing the photosensitivity of the camera under panel in the camera under panel area.

### DESCRIPTION OF DRAWINGS

FIG. 1 is a schematic cross-sectional structure diagram of an organic light emitting element according to an embodiment of the present disclosure.

FIG. 2 is a partial enlarged view of FIG. 1.

FIG. 3 is a schematic plane structure diagram of an organic light emitting element according to an embodiment of the present disclosure.

FIG. 4 is a schematic plane structure diagram of another organic light emitting element according to an embodiment of the present disclosure.

FIG. 5 is a schematic cross-sectional structure diagram of a display device according to an embodiment of the present disclosure.

FIG. 6 is a flowchart of a manufacturing method of an organic light emitting element according to an embodiment of the present disclosure.

FIG. 7 is a flowchart of preparing an array substrate in FIG. 6.

FIG. 8 is a flowchart of preparing a sub-pixel in FIG. 6.

The components in figures are identified as follows.
1: array substrate, 2: pixel definition layer, 3: anode layer, 4: sub-pixel, 5: cathode line, 6: thin film encapsulation layer, 7: light emitting layer, 8: cathode layer, 10: display area, 20: camera under panel area, 30: sensor, 11: glass substrate, 12: interlayer insulating layer, 13: flat organic layer, 21: recess, 41: red sub-pixel, 42: green sub-pixel, 43: blue sub-pixel, 100: organic light emitting element, 101: cathode layer, 200: display device, 211: red sub-pixel recess, 212: green sub-pixel recess, and 213: blue sub-pixel recess.

### DETAILED DESCRIPTION OF PREFERRED EMBODIMENTS

The foregoing objects, features and advantages adopted by the present disclosure can be best understood by referring to the following detailed description of the preferred embodiments and the accompanying drawings. Furthermore, the directional terms described in the present disclosure, such as upper, lower, front, rear, left, right, inner, outer, side, etc., are only directions referring to the accompanying drawings, so that the used directional terms are used to describe and understand the present disclosure, but the present disclosure is not limited thereto. In the drawings, similar structural units are designated by the same reference numerals.

In the drawings, the thickness of layers and regions are exaggerated for clarity. For example, the thicknesses and sizes of elements in the drawings are arbitrarily shown for convenience of description, thus, the spirit and scope of the described technology are not necessarily defined by the drawings.

In the present disclosure, the terms “install”, “be linked to”, “connect to”, “fix”, and the like, should be understood in generalization, unless specifically defined otherwise. For example, these terms are described as fixed joint, removable connection, or the integration of the connection; or mechanical joint or electrical connection; or direct connection or indirect connection via the middle medium, or internal connection between two components or interaction between two components. Those skilled in the art can understand the specific meaning about these terms in the present disclosure according to the specific circumstance.

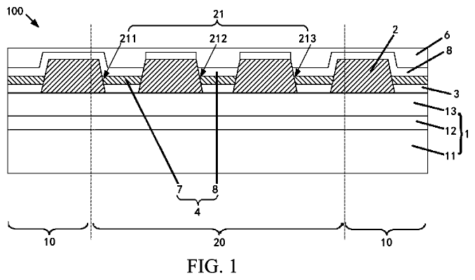

Referring to FIG. 1 to FIG. 4, a first embodiment of the present disclosure provides an organic light emitting element 100 provided with a display area 10 and a camera under panel area 20. The camera under panel area 20 is circular, rectangular, or polygonal. The camera under panel area 20 comprises an array substrate 1, a pixel definition layer 2, an anode layer 3, a plurality of sub-pixels 4, and at least one cathode line 5. Particularly, the pixel definition layer 2 is provided on the array substrate 1 and provided with a plurality of recesses 21. The anode layer 3 is provided on a bottom of the recesses 21. The plurality of sub-pixels 4 are provided on the corresponding anode layer 3 in the recesses 21. The cathode line 5 is provided on the pixel definition layer 2 and connected to the plurality of sub-pixels 4 in series, and two ends of the cathode line 5 extend and are connected to a cathode layer 8 located in the display area 10. The cathode layer 8 and the cathode line 5 are located in the same layer and are electrically connected to each other.

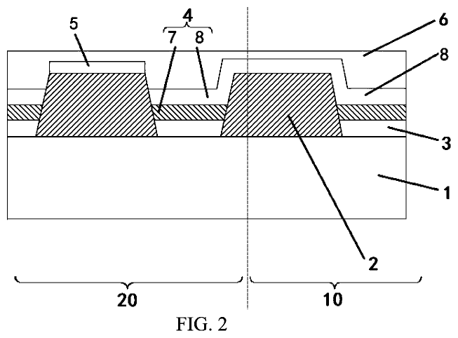

Referring to FIG. 2, which is a partial enlarged view of FIG. 1, the sub-pixels 4 comprise a light emitting layer 7 and the cathode layer 8. The light emitting layer 7 is provided on the anode layer 3 in the corresponding recess 21. The cathode layer 8 is provided on the light emitting layer 7 and completely covers an upper surface of the light emitting layer 7. That is, the light emitting layer 7 and the cathode layer 8 are both disposed in a diamond shape. The cathode layer 8 is electrically connected to the cathode line 5. It can be understood that, the cathode layer 8 and the cathode line 5 may be integrally formed. The materials of the two are the same, comprising indium tin oxide, which are transparent materials and can improve the transmittance, thereby improving the intensity of light passing through the camera under panel area 20.

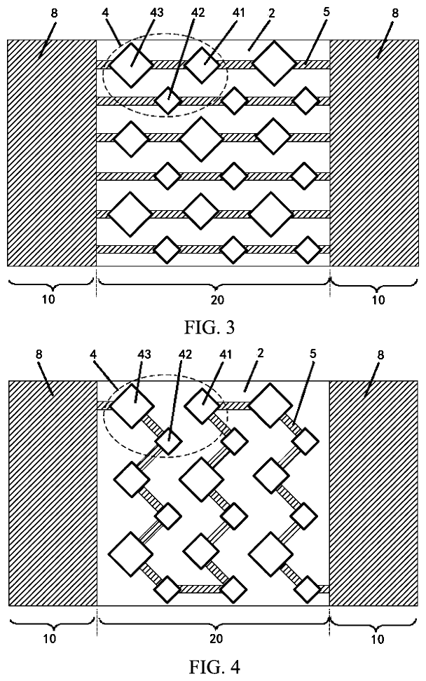

Referring to FIG. 3, the array substrate 1 is a thin film transistor substrate. The thin film transistor (not shown) is located in the display area 10, and is electrically connected to the cathode line 5 in the camera under panel area 20 by the cathode layer 8 located in the display area 10, so as to achieve the display control of the plurality of sub-pixels 4. Thus, the transmittance is maximized while the display screen of the camera under panel area 20 is achieved, thereby improving the intensity of light passing through the camera under panel area 20.

The materials of the anode layer 3, the cathode line 5, and the cathode layer 8 comprise indium tin oxide, which are transparent materials and can improve the transmittance, thereby improving the intensity of light passing through the camera under panel area 20.

In the present embodiment, the array substrate 1 located in the camera under panel area 20 comprises a glass substrate 11, an interlayer insulating layer 12, and a flat organic layer 13. The interlayer insulating layer 12 is provided on the glass substrate 11. The flat organic layer 13 is provided on the interlayer insulating layer 12, wherein the pixel definition layer 2 is provided on the flat organic layer 13.

Referring to FIG. 3 and FIG. 4, the cathode line 5 is linear, wavy, arc-shaped, or S-shaped, and is provided on the pixel definition layer 2. That is, the cathode line 5 is provided on a surface of the pixel definition layer 2 away from a side of the array substrate 1. The difference between the schematic plane structure diagrams of the organic light emitting element 100 shown in FIG. 3 and FIG. 4 is that, the cathode line 5 in FIG. 3 is a plurality of straight lines, and the cathode line 5 in FIG. 4 is a wavy line, as long as the cathode located in the camera under panel area 20, i.e., the cathode line 5, is reserved, and the cathode line can be in any shape to connect the plurality of sub-pixels 4.

In the present embodiment, the recesses 21 comprise at least one red sub-pixel recess 211, at least one green sub-pixel recess 212, and at least one blue sub-pixel recess 213. The sub-pixels 4 comprise at least one red sub-pixel 41, at least one green sub-pixel 42, and at least one blue sub-pixel recess 43 respectively disposed in the corresponding red sub-pixel recess 211, green sub-pixel recess 212, and blue sub-pixel recess 213. The red sub-pixel 41, the green sub-pixel 42, and the blue sub-pixel 43 are prepared by inkjet printing.

The sub-pixels 4 are disposed at intervals in an array in the camera under panel area 20. The sub-pixels 4 are disposed in a diamond shape. That is, the recesses 21 are also disposed in a diamond shape. An area of the green sub-pixel 42 is smaller than an area of the blue sub-pixel 43, and an area of the red sub-pixel 41 is between the area of the green sub-pixel 42 and the area of the blue sub-pixel 43. Correspondingly, an area of the green sub-pixel recess 212 is smaller than an area of the blue sub-pixel recess 213, and an area of the red sub-pixel recess 211 is between the area of the green sub-pixel recess 212 and the area of the blue sub-pixel recess 213.

In the present embodiment, the organic light emitting element 100 further comprises a thin film encapsulation layer 6 provided on the cathode line 5. More particularly, the thin film encapsulation layer 6 covers the organic light emitting element 100. The thin film encapsulation layer 6 comprises an inorganic water blocking layer or an organic buffer layer, and a stacked structure of the two.

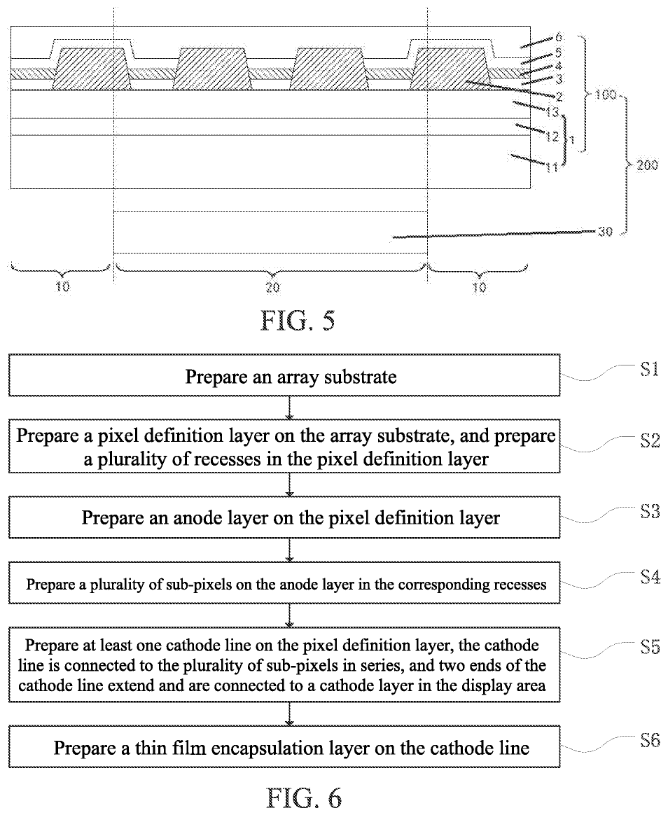

Referring to FIG. 5, another embodiment of the present disclosure further provides a display device 200 comprising the aforementioned organic light emitting element 100 and a sensor 30, wherein the sensor 30 is located below the organic light emitting element 100, and the camera under panel area 20 is disposed corresponding to a position of the sensor 30.

In the present embodiment, the sensor 30 comprises one or a combination of a camera sensor, a breathing light sensor, a distance sensor, a fingerprint scanner sensor, a microphone sensor, and a transparent antenna sensor.

The display device 200 of the present disclosure may be applied to various occasions, and may be combined with various elements and structures. The display device 200 may be either a mobile terminal (a mobile phone or a smart wear) or a fixed terminal (a PC), or other devices with a display function, such as a tablet computer, a television, and a display window. It should be understood that, to achieve the function, the display device 200 of the present disclosure is provided with other elements, structures, and the like, which are not shown in the present specification.

The display device 200 of the present disclosure improves the transmittance in the camera under panel area 20 by replacing the cathode layer located in the camera under panel area 20 with the cathode line 5, thereby improving the intensity of light passing through the camera under panel area 20, and enhancing the photosensitivity of the sensor 30, preferably the camera sensor, in the camera under panel area 20, namely, the photosensitivity of the camera under panel.

Referring to FIG. 6, another embodiment of the present disclosure further provides a manufacturing method of the organic light emitting element 100 comprising steps S1 to S5 as follows.

Step S1: an array substrate 1 is prepared.

Step S2: a pixel definition layer 2 is prepared on the array substrate 1, and a plurality of recesses are prepared in the pixel definition layer 2.

Step S3: an anode layer 3 is prepared on the pixel definition layer 2.

Step S4: a plurality of sub-pixels 4 are prepared on the anode layer 3 in the corresponding recesses. The sub-pixels 4 comprise a light emitting layer 7 and a cathode layer 8. The light emitting layer 7 is provided on the anode layer 3 in the corresponding recess 21. The cathode layer 8 is provided on the light emitting layer 7 and completely covers an upper surface of the light emitting layer 7. The sub-pixels 4 comprise at least one red sub-pixel 41, at least one green sub-pixel 42, and at least one blue sub-pixel 43. The red sub-pixel 41, the green sub-pixel 42, and the blue sub-pixel 43 are prepared by inkjet printing.

Step S5: at least one cathode line 5 is prepared on the pixel definition layer 2. The cathode line 5 is connected to the plurality of sub-pixels 4 in series, and two ends of the cathode line 5 extend and are connected to a cathode layer 8 in the display area 10. The cathode line 5 is linear, wavy, arc-shaped, or S-shaped.

Referring to FIG. 6, in the present embodiment, the manufacturing method of the organic light emitting element 100 further comprises steps as follows.

Step S6: a thin film encapsulation layer 6 is prepared on the cathode line 5. The thin film encapsulation layer 6 is formed by alternately depositing the inorganic water blocking layer and the organic buffer layer. A material of the inorganic water blocking layer may be SiNₓ, SiOₓ, SiOₓN_{y}, AlOₓ, HfOₓ, TiOₓ, etc., which may be formed by an atomic layer deposition (ALD) process, a pulsed laser deposition (PLD) process, a sputtering process, a plasma enhanced chemical vapor deposition (PECVD) process, or other processes. A material of the organic buffer layer may be acrylate, an epoxy resin, hexamethyldisiloxane (HMDSO), alucone, polystyrene, etc., which may be prepared by inkjet printing (IJP), plasma enhanced chemical vapor deposition (PECVD), or other processes. The thin film encapsulation layer 6 is used to block water and oxygen, so as to improve the service life of the organic light emitting element.

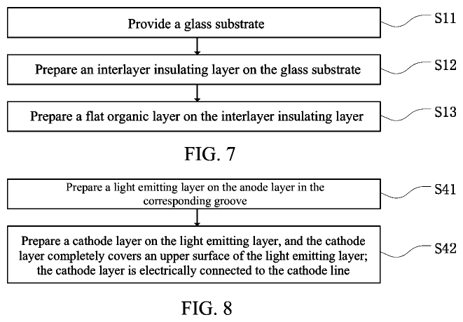

Referring to FIG. 7, in the present embodiment, wherein the step S1 of preparing the array substrate 1 particularly comprises steps as follows.

Step S11: a glass substrate 11 is provided.

Step S12: an interlayer insulating layer 12 is prepared on the glass substrate 11.

Step S13: a flat organic layer 13 is prepared on the interlayer insulating layer 12.

Referring to FIG. 8, in the present embodiment, the step of preparing the sub-pixels 4 comprises steps as follows.

Step S41: a light emitting layer 7 is prepared on the anode layer 3 in the corresponding recess 21.

Step S42: a cathode layer 8 is prepared on the light emitting layer 7. The cathode layer 8 completely covers an upper surface of the light emitting layer 7. The cathode layer 8 is electrically connected to the cathode line 5.

The cathode layer 8 and the cathode line 5 are in the same layer and are electrically connected to each other, and the materials of the two are the same, so the two can be prepared and patterned at the same time, and can be integrally disposed.

The technical effect of the present disclosure is as follows. An organic light emitting element, a display device, and a manufacturing method of the organic light emitting element are provided. By replacing the cathode layer located in the camera under panel area with the cathode line, the transmittance in the camera under panel area is improved, thereby improving the intensity of light passing through the camera under panel area, and enhancing the photosensitivity of the camera under panel in the camera under panel area.

The above is only a preferred embodiment of the present disclosure. It should be noted that, for those skilled in the art, without departing from the principles of the present disclosure, several improvements and modifications can be made. These should also be regarded as the protection scope of the present disclosure.

What is claimed is:

1. An organic light emitting element, provided with a display area and a camera under panel area,
wherein the camera under panel area comprises:
an array substrate;
a pixel definition layer provided on the array substrate and provided with a plurality of recesses;
an anode layer provided in the recesses;
a plurality of sub-pixels provided on the anode layer in corresponding recesses; and
at least one cathode line provided on the pixel definition layer and connected to the plurality of sub-pixels in series, wherein two ends of the cathode line extend and are electrically connected to a cathode layer located in the display area.

2. The organic light emitting element according to claim 1, wherein the cathode line is linear, wavy, arc-shaped, or S-shaped.

3. The organic light emitting element according to claim 1, wherein the sub-pixels comprise:
a light emitting layer provided on the anode layer in a corresponding recess; and
the cathode layer provided on the light emitting layer and completely covering an upper surface of the light emitting layer; wherein the cathode layer is electrically connected to the cathode line.

4. The organic light emitting element according to claim 1, wherein the sub-pixels comprise at least one red sub-pixel, at least one green sub-pixel, and at least one blue sub-pixel.

5. The organic light emitting element according to claim 1, further comprising: a thin film encapsulation layer provided on the cathode line.

6. A display device, comprising the organic light emitting element according to claim 1 and a sensor, wherein the camera under panel area is disposed corresponding to a position of the sensor.

7. The display device according to claim 6, wherein the sensor comprises one or a combination of a camera sensor, a breathing light sensor, a distance sensor, a fingerprint scanner sensor, a microphone sensor, and a transparent antenna sensor.

8. A manufacturing method of an organic light emitting element, comprising steps of:
preparing an array substrate;
preparing a pixel definition layer on the array substrate, and preparing a plurality of recesses in the pixel definition layer;
preparing an anode layer on the pixel definition layer;
preparing a plurality of sub-pixels on the anode layer in corresponding recesses; and
preparing at least one cathode line on the pixel definition layer, wherein the cathode line is connected to the plurality of sub-pixels in series, and two ends of the cathode line extend and are connected to a cathode layer in the display area.

9. The manufacturing method of the organic light emitting element according to claim 8, further comprising:
preparing a thin film encapsulation layer on the cathode line.

10. The manufacturing method of the organic light emitting element according to claim 8, wherein the step of preparing the sub-pixels comprises steps of:
preparing a light emitting layer on the anode layer in the corresponding recess; and
preparing a cathode layer on the light emitting layer, wherein the cathode layer completely covers an upper surface of the light emitting layer;
wherein the cathode layer is electrically connected to the cathode line.
